(19) United States
(12) Patent Application Publication
(10) Pub. No.: US 2025/0291961 A1
(43) Pub. Date: Sep. 18, 2025

(54) METHOD AND DEVICE FOR DETERMINING POSITIONS OF LAMP BEADS OF LED LIGHT STRING IN THREE-DIMENSIONAL LAYOUT

(71) Applicant: JM Zengge Co., Ltd., Jiangmen (CN)

(72) Inventors: Fuzhou Lin, Jiangmen (CN); Mingchang Zhou, Jiangmen (CN); Chuangda Nie, Jiangmen (CN)

(21) Appl. No.: 19/035,267

(22) Filed: Jan. 23, 2025

Related U.S. Application Data
(63) Continuation of application No. PCT/CN2024/126469, filed on Oct. 22, 2024.

(30) Foreign Application Priority Data
Mar. 15, 2024 (CN) 202410304386.9

(51) Int. Cl. G06F 30/12; F21S 4/10

(52) U.S. Cl. CPC G06F 30/12; F21S 4/10

(57) ABSTRACT

The present application discloses a method and device for determining positions of lamp beads of an LED light string in a three-dimensional layout, wherein, first, a plurality of LED light string images are acquired from a front side for lamp bead identification, to obtain a plurality of groups of point sets; an offset error is calculated from the denoised point set; a two-dimensional coordinate model of lamp beads on the front side is obtained from the aligned point set; similarly, a two-dimensional coordinate model of lamp beads on the reverse side can be obtained, and a two-dimensional lamp bead model containing front and rear sides is obtained. The present application is able to accurately obtain position coordinates of lamp beads on the rear side, such that the lamp beads on the rear side can achieve normal playing when animation effects are played.

### CROSS-REFERENCE TO RELATED APPLICATIONS

This application is a continuation of International Application No. PCT/CN2024/126469, filed on Oct. 22, 2024, which claims priority to China Patent Application No. CN202410304386.9, entitled “METHOD AND DEVICE FOR DETERMINING POSITIONS OF LAMP BEADS OF LED LIGHT STRING IN THREE-DIMENSIONAL LAYOUT”, filed to the China Patent Office on Mar. 15, 2024, the entire contents of which are incorporated in the present application by reference.

### TECHNICAL FIELD

The present application relates to the technical field of lamp bead position identification, and specifically relates to a method and device for determining positions of lamp beads of an LED light string in a three-dimensional layout.

### BACKGROUND

Colorful light strings are a novel LED decorative light fitting, and are usually used for festivals, celebration activities or indoor and outdoor decoration. They consist of strings of small light bulbs, which can present various colors and flashing effects, giving people a colorful and warm visual experience, such as FIG. 1. During festival seasons or special occasions, people often use colorful light strings to decorate rooms, courtyards, trees and other places to create a romantic and warm atmosphere.

Each lamp bead of the colorful light string contains a control integrated circuit (i.e., control IC), such that a control system can independently control each IC address. At present, outdoor landscape lights on the market can achieve animation play effects on a 2D screen. Each LED light of the outdoor landscape lights is pre-fixed in position, and then pixel coordinates of animations and images are mapped to an address corresponding to the colorful LED light to realize display and play effects of the animations and the images.

In the patent with the publication number: CN115460316B, a position of each colorful LED lamp is identified by photographing with a mobile phone camera. An address and a coordinate of each lamp bead can be identified through shot pictures and an image identification technology, thus forming a two-dimensional planar shape. In this way, various patterns can be displayed and cool animation effects can be achieved on this two-dimensional plane.

Please refer to FIG. 2 and FIG. 3. In many usage scenarios, users need to wrap the colorful light strings around various object surfaces at will, such as Christmas trees, fences or cylinders, etc. Using a method of the prior art, addresses and coordinates of lamp beads on one surface can only be identified, and addresses and coordinates of lamp beads in a blocked part on a rear side cannot be identified. The addresses and coordinates on the rear side can only be inferred according to the addresses of adjacent lamp beads, and corresponding addresses cannot be accurately identified.

Since the addresses and the coordinates of the lamp beads in the blocked part on the rear side cannot be accurately identified, when an animation effect is played, lamp beads on a front side can display a normal play screen, but lamp beads on the rear side will cause animation play disorder due to inaccurate coordinate addresses.

The patent document with the publication number CN116057572A, and the patent title “Method for determining three-dimensional positions of a plurality of lighting devices” mentions a manner that a plurality of two-dimensional models can be identified by moving a camera, and then the plurality of two-dimensional code models can be merged into a three-dimensional model, but a specification does not propose a specific merging method and algorithm, and in the patent document, it is needed to photograph at least 3 two-dimensional models for each point to generate a three-dimensional coordinate model, so it is needed to move in different directions to photograph at least 3 times or more, resulting in a complicated operation process.

### SUMMARY

To this end, the present application provides a method and device for determining positions of lamp beads of an LED light string in a three-dimensional layout, so as to solve the problem that the prior art cannot accurately identify positions of lamp beads at a blocked part on a rear side, resulting in animation play disorder.

In order to achieve the foregoing purpose, the present application provides the following technical solutions:
first aspect is a method for determining positions of lamp beads of an LED light string in a three-dimensional layout, comprising:
step 1: acquiring a plurality of LED light string images from a front side for lamp bead identification, to obtain a plurality of groups of point sets;
step 2: mapping the plurality of groups of point sets into one plane and performing noise reduction processing to obtain a denoised point set;
step 3: calculating an offset error from the denoised point set, and overlapping and aligning identical points according to the offset error;
step 4: obtaining a two-dimensional coordinate model of lamp beads on the front side from the aligned point set;
step 5: acquiring a plurality of LED light string images from a reverse side for lamp bead identification, to obtain a plurality of groups of point sets;
step 6: mapping the plurality of groups of point sets into one plane and performing noise reduction processing to obtain a denoised point set;
step 7: calculating an offset error from the denoised point set, and overlapping and aligning identical points according to the offset error;
step 8: obtaining a two-dimensional coordinate model of lamp beads on the reverse side from the aligned point set;
step 9: performing horizontal flipping, scaling transformation, rotation transformation and translation transformation on the two-dimensional coordinate model of the lamp beads on the reverse side and then overlapping the two-dimensional coordinate model of the lamp beads on the reverse side with the two-dimensional coordinate model of the lamp beads on the front side, to obtain a two-dimensional lamp bead model containing front and rear sides.

Preferably, in the step 1 and the step 5, a computer vision technology and an image processing algorithm are used when lamp bead identification is performed.

Preferably, in the step 2 and the step 6, a coordinate distance is used as an index for noise point removal when noise reduction processing is performed.

Preferably, in the step 3 and the step 7, the offset error comprises a rotation error and a translation error.

A second aspect is a device for determining positions of lamp beads of an LED light string in a three-dimensional layout, comprising:
a first lamp bead identification device for acquiring a plurality of LED light string images from a front side for lamp bead identification, to obtain a plurality of groups of point sets;
a first noise reduction module for mapping the plurality of groups of point sets into one plane and performing noise reduction processing to obtain a denoised point set;
a first overlapping and aligning module for calculating an offset error from the denoised point set, and overlapping and aligning identical points according to the offset error;
a front-side two-dimensional model determination module for obtaining a two-dimensional coordinate model of lamp beads on the front side from the aligned point set;
a second lamp bead identification device for acquiring a plurality of LED light string images from a reverse side for lamp bead identification, to obtain a plurality of groups of point sets;
a second noise reduction module for mapping the plurality of groups of point sets into one plane and performing noise reduction processing to obtain a denoised point set;
a second overlapping and aligning module for calculating an offset error from the denoised point set, and overlapping and aligning identical points according to the offset error;
a reverse-side two-dimensional model determination module for obtaining a two-dimensional coordinate model of lamp beads on the reverse side from the aligned point set;
a front-reverse-side two-dimensional model overlapping module for performing horizontal flipping, scaling transformation, rotation transformation and translation transformation on the two-dimensional coordinate model of the lamp beads on the reverse side and then overlapping the two-dimensional coordinate model of the lamp beads on the reverse side with the two-dimensional coordinate model of the lamp beads on the front side, to obtain a two-dimensional lamp bead model containing front and rear sides.

A third aspect is computer equipment, comprising a memory storing a computer program and a processor, wherein, when executing the computer program, the processor implements the steps of a method for determining positions of lamp beads of an LED light string in a three-dimensional layout.

A fourth aspect is a computer-readable storage medium having a computer program stored thereon, which, when executed by a processor, implements the steps of a method for determining positions of lamp beads of an LED light string in a three-dimensional layout.

A fifth aspect is a computer program product, comprising a computer program/instructions, which, when executed by a processor, implement(s) the steps of a method for determining LED light string lamp bead positions in a three-dimensional layout.

Compared with the prior art, the present application at least has the following beneficial effects:

the present application provides a method and device for determining positions of lamp beads of an LED light string in a three-dimensional layout. First, a plurality of LED light string images are acquired from a front side for lamp bead identification, to obtain a plurality of groups of point sets; the plurality of groups of point sets are mapped into one plane, and noise reduction processing is performed to obtain a denoised point set; an offset error is calculated from the denoised point set, and identical points are overlapped and aligned according to the offset error; a two-dimensional coordinate model of lamp beads on the front side is obtained from the aligned point set; similarly, a two-dimensional coordinate model of lamp beads on a reverse side can be obtained, finally horizontal flipping, scaling transformation, rotation transformation and translation transformation are performed on the two-dimensional coordinate model of the lamp beads on the reverse side, and then the two-dimensional coordinate model of the lamp beads on the reverse side is overlapped with the two-dimensional coordinate model of the lamp beads on the front side to obtain a two-dimensional lamp bead model containing front and rear sides. The present application is able to accurately obtain position coordinates of lamp beads on the rear side, such that the lamp beads on the rear side can achieve normal playing when animation effects are played.

### BRIEF DESCRIPTION OF DRAWINGS

In order to more intuitively illustrate the prior art and the present application, exemplary drawings are given below. It should be understood that specific shapes and structures shown in the drawings should generally not be regarded as limiting conditions when the present application is implemented; for example, based on technical concepts and exemplary drawings disclosed in the present application, those skilled in the art will be able to easily make routine adjustments or further optimization for addition/subtraction/attribution division, specific shape, positional relationship, connection method, size proportion relationship, etc. of certain units (components).

FIG. 1 is a schematic decoration diagram of a colorful light string;

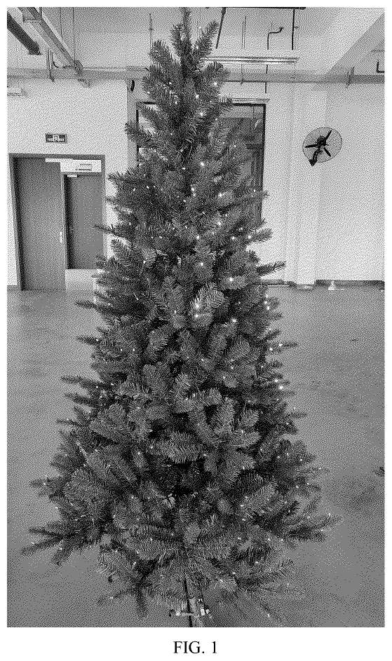

FIG. 2 is a schematic view of a front side of a use scenario of the colorful light string;

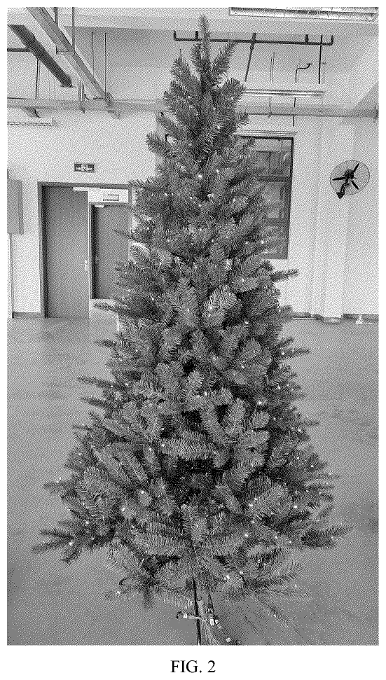

FIG. 3 is a schematic diagram of a reverse side of the use scenario of the colorful light string;

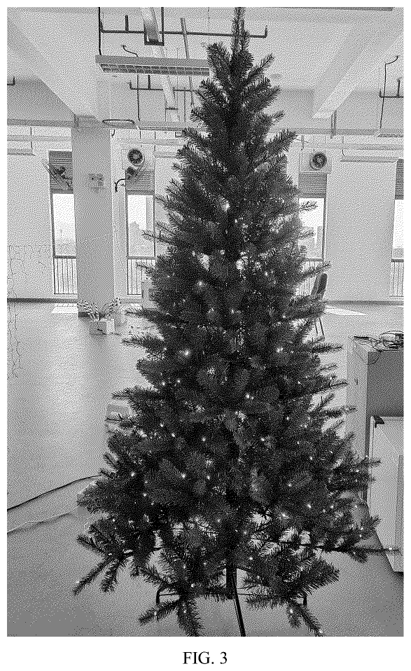

FIG. 4 is a flow chart of a method for determining positions of lamp beads of an LED light string in a three-dimensional layout provided by Embodiment 1 of the present application;

FIG. 5 is a schematic diagram 1 of acquiring a front-side LED light string image provided by Embodiment 1 of the present application;

FIG. 6 is a schematic diagram 2 of acquiring the front-side LED light string image provided by Embodiment 1 of the present application;

FIG. 7 is a schematic diagram of mapping a plurality of groups of point sets to one plane provided by Embodiment 1 of the present application;

FIG. 8 is a schematic distance diagram of each group of points provided by Embodiment 1 of the present application;

FIG. 9 is a schematic diagram 1 of determining a point set with minimum noise provided by Embodiment 1 of the present application;

FIG. 10 is a schematic diagram 2 of determining the point set with minimum noise provided by Embodiment 1 of the present application;

FIG. 11 is a schematic diagram of acquiring a reverse-side LED light string image provided by Embodiment 1 of the present application.

### DESCRIPTION OF EMBODIMENTS

The present application will be further described in detail below through specific embodiments in conjunction with drawings.

In descriptions of the present application, unless otherwise specified, “a plurality of” means two or more than two. Terms “first”, “second”, “third”, etc. in the present application are intended to distinguish objects referred to, but do not have special meaning in terms of technical connotation (for example, they should not be understood as emphasizing an importance degree or order, etc.). Expressions such as “comprise”, “contain” and “have” also mean “not limited to” (certain units, components, materials, steps, etc.).

Words such as “upper”, “lower”, “left”, “right”, “middle”, etc. cited in the present application are usually indications made on general relative positional relationships for facilitating intuitive understanding with reference to the drawings, and are not absolute limitations on positional relationships in an actual product.

### Embodiment 1

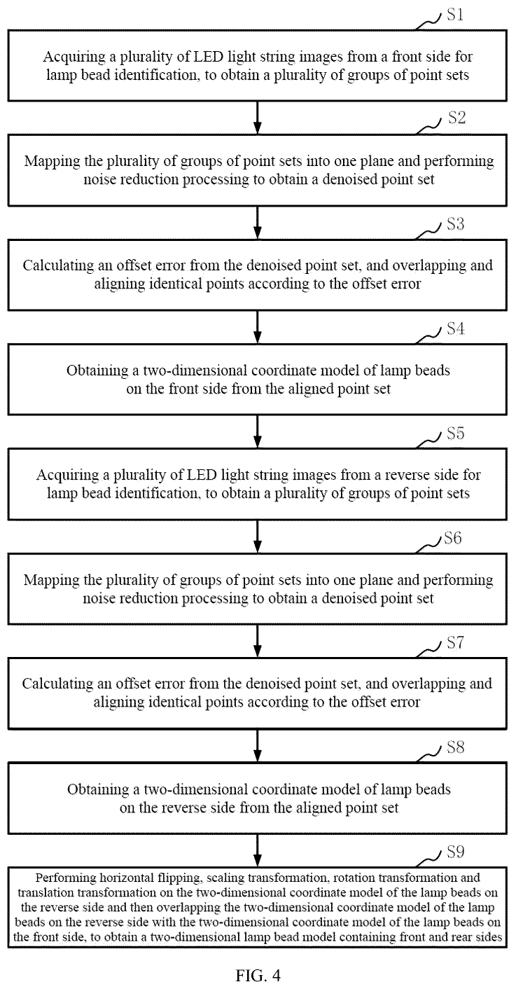

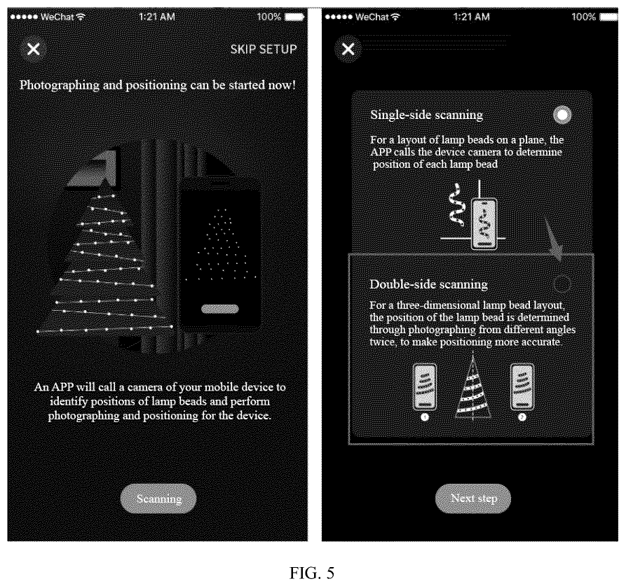

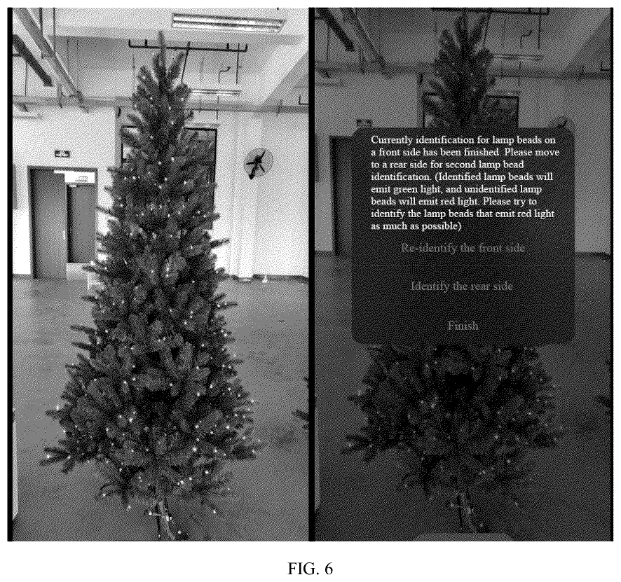

Please refer to FIG. 4. The present embodiment provides a method for determining positions of lamp beads of an LED light string in a three-dimensional layout, comprising:
S1: acquiring a plurality of LED light string images from a front side for lamp bead identification, to obtain a plurality of groups of point sets;
referring to FIG. 5 and FIG. 6, in this embodiment, a light string control APP installed in a smart device can be used to photograph a front side of a three-dimensional object provided with LED light strings from different angles multiple times, thereby acquiring a plurality of LED light string images.

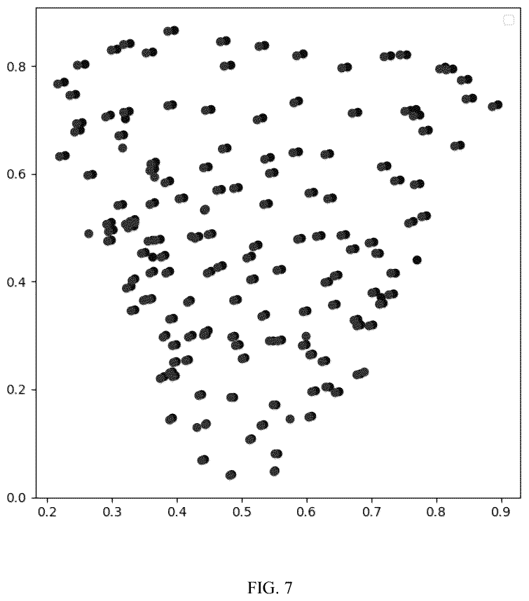

After acquiring the plurality of LED light string images, the light string control APP can use a computer vision technology and an image processing algorithm to identify lamp beads in the plurality of LED light string images. Once the lamp beads in the LED light string images are identified, a point set can be generated according to position information of the lamp beads, and each point represents a position coordinate of one lamp bead in an image. For example: after two LED light string images are acquired, two groups of point sets x and x′ can be obtained.
S2: mapping a plurality of groups of point sets into one plane, and performing noise reduction processing to obtain a denoised point set;
referring to FIG. 7, as different degrees of noise will occur during photographing or target identification, the noise will result in that a plurality of groups of point sets are unable to be completely superposed, which will further seriously affect subsequent lamp bead position identification, so noise reduction processing is required, and the point sets are overlapped together after noise reduction processing. For example: taking two images as an example, after noise reduction processing, the point set x′ is overlapped to x.

In the present embodiment, a coordinate distance is used as an index for noise point removal when noise reduction processing is performed. Specifically, assuming that a Euclidean Distance D between the point sets x and x′ is calculated, a shortest distance is taken as a group of points to obtain corresponding C={(i,j)}.

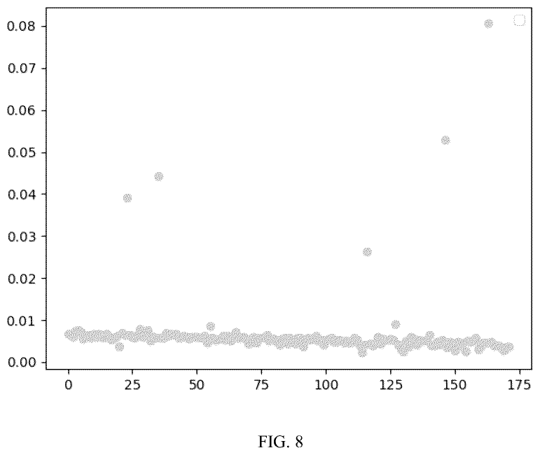

Please refer to FIG. 8, wherein D is:

D={d|d(xᵢ,xⱼ′)∈C}

Because target identification accuracy and photographing problems will cause noise in C, if the C mapping set is directly used for overlap calculation, it will lead to a large overlap error, so noise points existing in C need to be reduced.

In order to solve this problem, in the present embodiment, two points are randomly selected, a straight line is defined according to these two points, and then two straight lines are defined based on this straight line, namely, the first straight line is: yt=ax+(b+0.005), the second straight line is: y=ax+b, and the third straight line is: yb=ax+(b−0.005), and points within yt and yb are acquired. The above operations are repeated multiple times, and the line with the most points is usually a point set C′={(i,j)} with smallest noise.

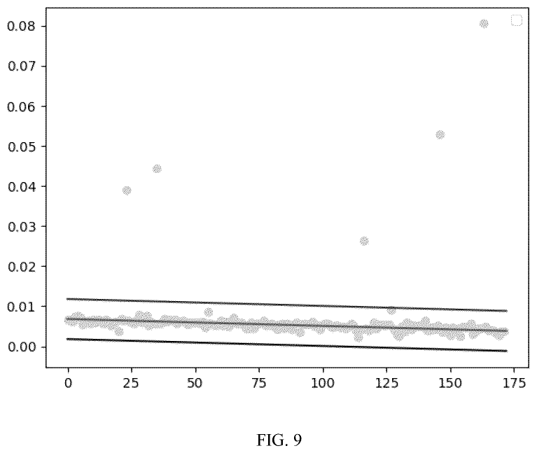

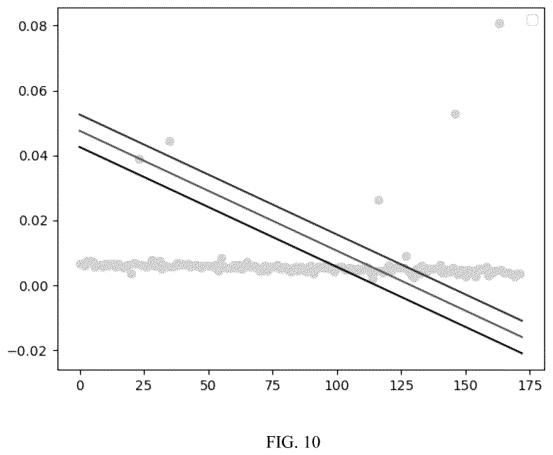

In other words, two points are randomly selected in a set D. The two points form a straight line, and then the straight line extends outward by +0.005 and −0.005. Referring to FIG. 9 and FIG. 10, obviously, the noise of a point set in FIG. 9 is smaller than that of a point set in FIG. 10, then the points falling within the straight line are called “inner points”. The operation is cycled multiple times, and then the points of the straight line with the most “inner points” are selected as a point set with the smallest noise, that is, a denoised point set C′.
S3: calculating an offset error from the denoised point set, and overlapping and aligning identical points according to the offset error;
after the point set C′ with the smallest noise is acquired, error correction is performed using this point set. x and x′ usually only differ by one rotation and translation transformation.

Specifically, first a point is translated, such that its centroid is located at an origin, namely:

$${u}^{′} = \frac{1}{‖ {C}^{′} ‖} {\sum }_{( i , j ) ∈ {C}^{′}} {x}_{i} {v}^{′} = \frac{1}{‖ {C}^{′} ‖} {\sum }_{( i , j ) ∈ {C}^{′}} {x}_{j}^{′}$$

$$\{ {x}_{i} - {u}^{′} \} = \{ {b}_{1}^{′} \}$$

$$\{ {x}_{j}^{′} - {v}^{′} \} = \{ {q}_{1}^{′} \}$$

Then a rotation error and a translation error are calculated, namely:

$$W = {\sum }_{( i , j ) ∈ {C}^{′}} {b}_{i}^{′} {q}_{j}^{′ T}$$

$$W = {UDV}^{T}$$

U and V are 2×2 two-dimensional orthogonal matrices, then a rotation matrix and a translation vector can be solved by a following method, namely:

$$R = {UV}^{T}$$

$$t = {u}^{′} - {Rv}^{′}$$

Finally, points are overlapped and aligned, namely:

$${x}^{′} ← R ( {x}^{′} - {υ}^{′} ) + {u}^{′}$$

Repeat the above steps a specified number of times or until convergence.
S4: obtaining a two-dimensional coordinate model of lamp beads on the front side from the aligned point set;
after a plurality of groups of point sets are aligned, a lamp bead position matrix of an LED light string image can be established, and then an actual position of each lamp bead in an LED light string, namely the two-dimensional coordinate model, is determined according to a lamp bead address matrix and the lamp bead position matrix of the LED light string.

Because a lamp bead of each LED light string has a fixed address, if you know the address of the lamp bead but do not know the position of the lamp bead, you can determine a specific position of the lamp bead address on a picture by changing a color of the lamp bead and then photographing by a mobile phone for color identification. Color changes of the lamp beads are limited to three colors: “red”, “green” and “blue”, and in addition, the repeated arrangement of the colors of each lamp bead must be unique to determine the position. So its color matrix is:

$$C = [ \begin{matrix}{c}_{11} & … & {c}_{1 n} \\ ⋮ & ⋱ & ⋮ \\ {c}_{m 1} & … & {c}_{mn}\end{matrix} ]$$

Therein, the number of rows of the matrix is the number of pictures, and columns are repeated arrangements of the colors of the lamp beads. For example: a number of lamp beads of a light string is 2000, then the size of C is C_{7×2000}, which means that 7 pictures need to be taken to determine that the color arrangement of the lamp beads is unique. This can be calculated easily: one lamp bead has 3 states, and in the case of 7 pictures, 3⁷>2000, so the color arrangement of the lamp beads can be uniquely determined.

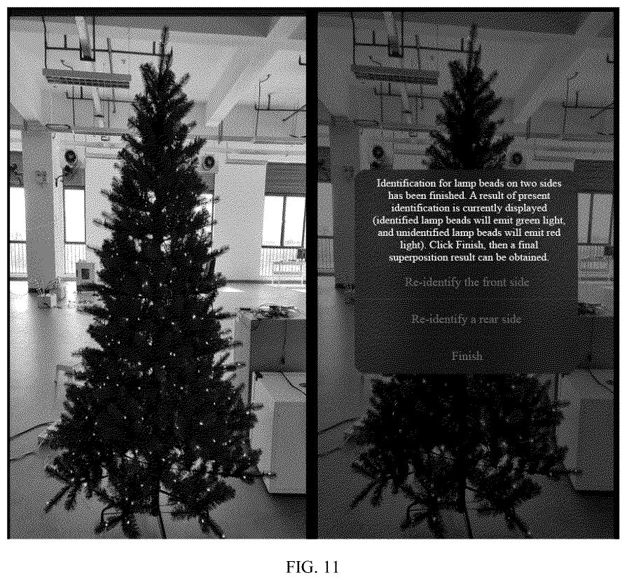

The above-mentioned method is clearly recorded in the patent with publication number: CN115460316B, and will not be described again herein.
S5: acquiring a plurality of LED light string images from a reverse side for lamp bead identification, to obtain a plurality of groups of point sets, see FIG. 11;
S6: mapping the plurality of groups of point sets into one plane and performing noise reduction processing to obtain a denoised point set;
S7: calculating an offset error from the denoised point set, and overlapping and aligning identical points according to the offset error;
S8: obtaining a two-dimensional coordinate model of lamp beads on a rear side from the aligned point set;
a method for determining the two-dimensional coordinate model of the lamp beads on the rear side is the same as the method for determining the two-dimensional coordinate model of the lamp beads on the front side, and will not be described again herein.
S9: performing horizontal flipping, scaling transformation, rotation transformation and translation transformation on the two-dimensional coordinate model of the lamp beads on the reverse side and then overlapping the two-dimensional coordinate model of the lamp beads on the reverse side with the two-dimensional coordinate model of the lamp beads on the front side, to obtain a two-dimensional lamp bead model containing front and rear sides.

Because coordinates of a two-dimensional coordinate model x_{f} of the lamp beads on the front side and those of a two-dimensional coordinate model x_{f} of the lamp beads on the reverse side differ on a mobile phone plane by one horizontal flipping, scaling transformation, rotation transformation and translation transformation, the two-dimensional coordinate model of the lamp beads on the reverse side can be subjected to horizontal flipping, scaling transformation, rotation transformation and translation transformation, and then overlapped with the two-dimensional coordinate model of the lamp beads on the front side to obtain a two-dimensional lamp bead model containing front and rear sides.

Specifically, a following method can be used to solve 4 transformations of horizontal flipping, scaling transformation, rotation transformation and translation transformation, to complete overlapping of front and reverse sides.

First, by a plurality of groups of coordinates, a corresponding matrix A={(i,j)} is found through an intersection of addresses;
then, horizontal flipping and scaling transformation are performed on a two-dimensional coordinate model x, of lamp beads on the reverse side, namely:

$${x}_{r}^{′} = {x}_{r}^{T} [ \begin{matrix}- cx & 0 \\ 0 & cy\end{matrix} ]$$

cx and cy are solved according to a least squares method, thus obtaining xᵣ′.

Finally, xᵣ′ is used to solve rotation transformation and translation transformation. A calculation method is the same as the method for calculating rotation and translation errors in the offset error, which will not be described again herein.

The present embodiment provides the method for determining positions of lamp beads of an LED light string in a three-dimensional layout, which uses a coordinate distance as an index for noise point removal, improving overlapping accuracy of points and generation accuracy of two-dimensional coordinate models of lamp beads on front and reverse sides. By first identifying a two-dimensional coordinate model of lamp beads on a front side, then identifying a two-dimensional coordinate model of lamp beads on a rear side, performing flipping and scaling transformation on the two-dimensional coordinate model of the lamp beads on the front side and the two-dimensional coordinate model of the lamp beads on the rear side, then overlapping points of the two-dimensional images together by calculating a rotation matrix and a translation vector, and generating a two-dimensional lamp bead model containing front and rear sides, the problem of being unable to accurately identify position coordinates of the lamp beads on the rear side is solved, such that the lamp beads on the rear side can achieve normal playing when animation effects are played.

### Embodiment 2

The present embodiment provides a device for determining positions of lamp beads of an LED light string in a three-dimensional layout, comprising:
a first lamp bead identification device for acquiring a plurality of LED light string images from a front side for lamp bead identification, to obtain a plurality of groups of point sets;
a first noise reduction module for mapping the plurality of groups of point sets into one plane and performing noise reduction processing to obtain a denoised point set;
a first overlapping and aligning module for calculating an offset error from the denoised point set, and overlapping and aligning identical points according to the offset error;
a front-side two-dimensional model determination module for obtaining a two-dimensional coordinate model of lamp beads on the front side from the aligned point set;
a second lamp bead identification device for acquiring a plurality of LED light string images from different angles on a reverse side for lamp bead identification, to obtain a plurality of groups of point sets;
a second noise reduction module for mapping the plurality of groups of point sets into one plane and performing noise reduction processing to obtain a denoised point set;
a second overlapping and aligning module for calculating an offset error from the denoised point set, and overlapping and aligning identical points according to the offset error;
a reverse-side two-dimensional model determination module for obtaining a two-dimensional coordinate model of lamp beads on the reverse side from the aligned point set;
a front-reverse-side two-dimensional model overlapping module for performing horizontal flipping, scaling transformation, rotation transformation and translation transformation on the two-dimensional coordinate model of the lamp beads on the reverse side and then overlapping the two-dimensional coordinate model of the lamp beads on the reverse side with the two-dimensional coordinate model of the lamp beads on the front side, to obtain a two-dimensional lamp bead model containing front and rear sides.

Regarding the specific implementation content of each module in the device for determining positions of lamp beads of an LED light string in a three-dimensional layout, you can refer to the above limitations on the method for determining positions of lamp beads of an LED light string in a three-dimensional layout, which will not be described again herein.

### Embodiment 3

The present embodiment provides computer equipment, comprising a memory storing a computer program and a processor, wherein, when executing the computer program, the processor implements the steps of a method for determining positions of lamp beads of an LED light string in a three-dimensional layout.

### Embodiment 4

The present embodiment provides a computer-readable storage medium having a computer program stored thereon, which, when executed by a processor, implements the steps of a method for determining positions of lamp beads of an LED light string in a three-dimensional layout.

### Embodiment 5

The present embodiment provides a computer program product, comprising a computer program/instruction(s), which, when executed by a processor, implement(s) the steps of a method for determining positions of lamp beads of an LED light string in a three-dimensional layout.

The technical features of the above embodiments can be combined arbitrarily (as long as there is no contradiction among combinations of these technical features). To make descriptions concise, not all possible combinations of the various technical features in the above embodiments are described; these embodiments not clearly written should also be considered as falling within the scope recorded in the specification.

1-5. (canceled)

6. A computer equipment, comprising a memory storing a computer program and a processor, wherein, when executing the computer program, the processor implements the following steps;
acquiring a plurality of LED light string images from a front side for lamp bead identification, to obtain a plurality of groups of point sets:
mapping the plurality of groups of point sets into one plane and performing noise reduction processing to obtain a denoised point set;
calculating an offset error from the denoised point set, and overlapping and aligning identical points according to the offset error;
obtaining a two-dimensional coordinate model of lamp beads on the front side from the aligned point set;
acquiring a plurality of LED light string images from a reverse side for lamp bead identification, to obtain a plurality of groups of point sets:
mapping the plurality of groups of point sets into one plane and performing noise reduction processing to obtain a denoised point set;
calculating an offset error from the denoised point set, and overlapping and aligning identical points according to the offset error;
obtaining a two-dimensional coordinate model of lamp beads on the reverse side from the aligned point set;
performing horizontal flipping, scaling transformation, rotation transformation and translation transformation on the two-dimensional coordinate model of the lamp beads on the reverse side and then overlapping the two-dimensional coordinate model of the lamp beads on the reverse side with the two-dimensional coordinate model of the lamp beads on the front side, to obtain a two-dimensional lamp bead model containing front and rear sides.

7. A non-transitory computer-readable storage medium, having a computer program stored thereon, which, when executed by a processor, implements the following steps:
acquiring a plurality of LED light string images from a front side for lamp bead identification, to obtain a plurality of groups of point sets;
mapping the plurality of groups of point sets into one plane and performing noise reduction processing to obtain a denoised point set;
calculating an offset error from the denoised point set, and overlapping and aligning identical points according to the offset error;
obtaining a two-dimensional coordinate model of lamp beads on the front side from the aligned point set;
acquiring a plurality of LED light string images from a reverse side for lamp bead identification, to obtain a plurality of groups of point sets;
mapping the plurality of groups of point sets into one plane and performing noise reduction processing to obtain a denoised point set:
calculating an offset error from the denoised point set, and overlapping and aligning identical points according to the offset error;
obtaining a two-dimensional coordinate model of lamp beads on the reverse side from the aligned point set;
performing horizontal flipping, scaling transformation, rotation transformation and translation transformation on the two-dimensional coordinate model of the lamp beads on the reverse side and then overlapping the two-dimensional coordinate model of the lamp beads on the reverse side with the two-dimensional coordinate model of the lamp beads on the front side, to obtain a two-dimensional lamp bead model containing front and rear sides.

8. A computer program product, comprising a computer program, which, when executed by a processor, implement the following steps;
acquiring a plurality of LED light string images from a front side for lamp bead identification, to obtain a plurality of groups of point sets;
mapping the plurality of groups of point sets into one plane and performing noise reduction processing to obtain a denoised point set;
calculating an offset error from the denoised point set, and overlapping and aligning identical points according to the offset error;
obtaining a two-dimensional coordinate model of lamp beads on the front side from the aligned point set;
acquiring a plurality of LED light string images from a reverse side for lamp bead identification, to obtain a plurality of groups of point sets:
mapping the plurality of groups of point sets into one plane and performing noise reduction processing to obtain a denoised point set;
calculating an offset error from the denoised point set, and overlapping and aligning identical points according to the offset error;
obtaining a two-dimensional coordinate model of lamp beads on the reverse side from the aligned point set;
performing horizontal flipping, scaling transformation, rotation transformation and translation transformation on the two-dimensional coordinate model of the lamp beads on the reverse side and then overlapping the two-dimensional coordinate model of the lamp beads on the reverse side with the two-dimensional coordinate model of the lamp beads on the front side, to obtain a two-dimensional lamp bead model containing front and rear sides.

9. The computer equipment according to claim 6, wherein a computer vision technology and an image processing algorithm are used when lamp bead identification is performed.

10. The computer equipment according to claim 6, wherein a coordinate distance is used as an index for noise point removal when noise reduction processing is performed.

11. The computer equipment according to claim 6, wherein the offset error comprises a rotation error and a translation error.

12. The non-transitory computer-readable storage medium according to claim 7, wherein a computer vision technology and an image processing algorithm are used when lamp bead identification is performed.

13. The non-transitory computer-readable storage medium according to claim 7, wherein a coordinate distance is used as an index for noise point removal when noise reduction processing is performed.

14. The non-transitory computer-readable storage medium according to claim 7, wherein the offset error comprises a rotation error and a translation error.

15. The computer program product according to claim 8, wherein a computer vision technology and an image processing algorithm are used when lamp bead identification is performed.

16. The computer program product according to claim 8, wherein a coordinate distance is used as an index for noise point removal when noise reduction processing is performed.

17. The computer program product according to claim 8, wherein the offset error comprises a rotation error and a translation error.
